(19) United States
(12) Patent Application Publication
(10) Pub. No.: US 2016/0254126 A1
(43) Pub. Date: Sep. 1, 2016

(54) APPARATUS AND METHODS FOR MODIFYING WEBS OF MATERIAL WITH PLASMA

(71) Applicant: Curt G. Joa, Inc., Sheboygan Falls, WI (US)

(72) Inventors: Sudeep Ingole, Sheboygan, WI (US); Lloyd Kreif, Sheboygan Falls, WI (US); Brenden Schulz, Sheboygan, WI (US)

(73) Assignee: Curt G. Joa, Inc., Sheboygan Falls, WI (US)

(21) Appl. No.: 15/054,802

(22) Filed: Feb. 26, 2016

Related U.S. Application Data
(60) Provisional application No. 62/120,989, filed on Feb. 26, 2015.

(51) Int. Cl. H01J 37/32

(52) U.S. Cl. CPC H01J 37/32568; H01J 37/32871; H01J 2237/334; H01J 2237/33

(57) ABSTRACT

Using electrostatic means, such as plasma, webs can be cut, and webs can be bonded together. A plasma is created and directed at an intervening poly or a nonwoven to sever the fabric, either continuously or intermittently, or to bond and sever two more material layers together.

### RELATED APPLICATION

This application claims the benefit of co-pending U.S. Provisional Patent Application No. 62/120,989, filed 26 Feb. 2015.

### BACKGROUND OF THE INVENTION

This invention relates to a method and apparatus for rapidly and accurately modifying, such as by cutting or bonding, discrete articles or a web or webs of material by using a generated plasma field to modify on a microscopic level the individual fibers of the material or fabric.

Generally, diapers comprise an absorbent insert or patch and a chassis, which, when the diaper is worn, supports the insert proximate a wearer's body. Additionally, diapers may include other various patches, such as tape tab patches, reusable fasteners and the like. The raw materials used in forming a representative insert are typically cellulose pulp, tissue paper, poly, nonwoven web, acquisition, and elastic, although application specific materials are sometimes utilized. Usually, most of the insert raw materials are provided in roll form, and unwound and applied in continuously fed fashion.

In the creation of a diaper, multiple roll-fed web processes are typically utilized. To create an absorbent insert, the cellulose pulp is unwound from the provided raw material roll and de-bonded by a pulp mill. Discrete pulp cores are created using a vacuum forming assembly and placed on a continuous tissue web. Optionally, super-absorbent powder may be added to the pulp core. The tissue web is wrapped around the pulp core. The wrapped core is debulked by proceeding through a calender unit, which at least partially compresses the core, thereby increasing its density and structural integrity. After debulking, the tissue-wrapped core is passed through a segregation or knife unit, where individual wrapped cores are cut. The cut cores are conveyed, at the proper pitch, or spacing, to a boundary compression unit.

While the insert cores are being formed, other insert components are being prepared to be presented to the boundary compression unit. For instance, the poly sheet, is prepared to receive a cut core. Like the cellulose pulp, poly sheet material is usually provided in roll form. The poly sheet is fed through a splicer and accumulator, coated with an adhesive in a predetermined pattern, and then presented to the boundary compression unit. In addition to the poly sheet, which may form the bottom of the insert, a two-ply top sheet may also be formed in parallel to the core formation. Representative plies are an acquisition layer web material and a nonwoven web material, both of which are fed from material parent rolls, through a splicer and accumulator. The plies are coated with adhesive, adhered together, cut to size, and presented to the boundary compression unit. Therefore, at the boundary compression unit, three components are provided for assembly: the poly bottom sheet, the core, and the two-ply top sheet.

A representative boundary compression unit includes a profiled die roller and a smooth platen roller. When all three insert components are provided to the boundary compression unit, the nip of the rollers properly compresses the boundary of the insert. Thus, provided at the output of the boundary compression unit is a string of interconnected diaper inserts. The diaper inserts are then separated by an insert knife assembly and properly oriented, such as disclosed in co-pending U.S. Application No. 61/426,891, owned by the assignee of the present invention and incorporated herein by reference. At this point, the completed insert is ready for placement on a diaper chassis.

A representative diaper chassis comprises nonwoven web material and support structure. The diaper support structure is generally elastic and may include leg elastic, waistband elastic and belly band elastic. The support structure is usually sandwiched between layers of the nonwoven web material, which is fed from material rolls, through splicers and accumulators. The chassis may also be provided with several patches, besides the absorbent insert. Representative patches include adhesive tape tabs and resealable closures.

The process utilizes two main carrier webs; a nonwoven web which forms an inner liner web, and an outer web that forms an outwardly facing layer in the finished diaper. In a representative chassis process, the nonwoven web is slit at a slitter station by rotary knives along three lines, thereby forming four webs. One of the lines is on approximately the centerline of the web and the other two lines are parallel to and spaced a short distance from the centerline. The effect of such slitting is twofold.; first, to separate the nonwoven web into two inner diaper liners. One liner will become the inside of the front of the diaper, and the second liner will become the inside of the back of that garment. Second, two separate, relatively narrow strips are formed that may be subsequently used to cover and entrap portions of the leg-hole elastics. The strips can be separated physically by an angularly disposed spreader roll and aligned laterally with their downstream target positions on the inner edges of the formed liners. This is also done with turn bars upon entrance to the process.

After the nonwoven web is slit, an adhesive is applied to the liners in a predetermined pattern in preparation to receive leg-hole elastic. The leg-hole elastic is applied to the liners and then covered with the narrow strips previously separated from the nonwoven web. Adhesive is applied to the outer web, which is then combined with the assembled inner webs having elastic thereon, thereby forming the diaper chassis. Next, after the elastic members have been sandwiched between the inner and outer webs, an adhesive is applied to the chassis. The chassis is now ready to receive an insert.

In diapers it is preferable to contain elastics around the leg region in a cuff to contain exudates for securely within the diaper. Typically, strands of elastic are held by a non-woven layer that is folded over itself and contains the elastics within the overlap of the non-woven material. The non-woven is typically folded by use of a plow system which captures the elastics within a pocket, which is then sealed to ensure that the elastics remain in the cuff.

Most products require some longitudinal folding. It can be combined with elastic strands to make a cuff. It can be used to overwrap a stiff edge to soften the feel of the product. It can also be used to convert the final product into a smaller form to improve the packaging.

To assemble the final diaper product, the insert must be combined with the chassis. The placement of the insert onto the chassis occurs on a placement drum or at a patch applicator. The inserts are provided to u the chassis on the placement drum at a desired pitch or spacing. The generally flat chassis/insert combination is then folded so that the inner webs face each other, and the combination is trimmed. A sealer bonds the webs at appropriate locations prior to individual diapers being cut from the folded and sealed webs.

Roll-fed web processes typically use splicers and accumulators to assist in providing continuous webs during web processing operations. A first web is fed from a supply wheel (the expiring roll) into the manufacturing process. As the material from the expiring roll is depleted, it is necessary to splice the leading edge of a second web from a standby roll to the first web on the expiring roll in a manner that will not cause interruption of the web supply to a web consuming or utilizing device.

In a splicing system, a web accumulation dancer system may be employed, in which an accumulator collects a substantial length of the first web. By using an accumulator, the material being fed into the process can continue, yet the trailing end of the material can be stopped or slowed for a short time interval so that it can be spliced to leading edge of the new supply roll. The leading portion of the expiring roll remains supplied continuously to the web-utilizing device. The accumulator continues to feed the web utilization process while the expiring roll is stopped and the new web on a standby roll can be spliced to the end of the expiring roll.

In his manner, the device has a constant web supply being paid out from the accumulator, while the stopped web material in the accumulater can be spliced to the standby roll.

Some diaper forming techniques are disclosed in co-pending U.S. application Ser. No. 12/925,033 which is incorporated herein by reference. As described therein, a process wherein a rotary knife or die, with one or more cutting edges, turns against and in coordination with a corresponding cylinder to create preferably trapezoidal ears. Ear material is slit into two lanes, one for a left side of a diaper and the other for a right side of a diaper. Fastening tapes are applied to both the right and the left ear webs. The ear material is then die cut with a nested pattern on a synchronized vacuum anvil.

The resulting discrete ear pieces however, due to the trapezoidal pattern of the ears, alternate between a correct orientation and an incorrect (reversed) orientation. The reversed ear is required to be rotated 180° into the correct orientation such that the ears and associated tape present a left ear and a right ear on the diaper.

To accomplish the reversal of the ear pattern, discrete ear pieces are picked up at the nested ear pitch by an ear turner assembly that will expand to a pitch large enough for ears to be unnested and allow clearance for every other ear to be rotated. The rotated ears are then unnested and into the correct orientation.

Two ear turner assemblies can be provided, to rotate every other ear applied to the right side of the product, and every other ear applied to the left side of the product. In this manner, for a single product, one of the two ears will have been rotated 180°.

Continual improvements and competitive pressures have incrementally increased the operational speeds of disposable diaper converters. As speeds increased, the mechanical integrity and operational capabilities of the applicators had to be improved accordingly.

Knives are traditionally used throughout the manufacturing process to cut material, whether it be cutting pieces to fit on a disposable product, or severing a web or a line of material into individual products. Knives are often used on rotary mechanisms in conjunction with an anvil. A material is placed between a knife blade and an anvil, and the knife acts to sever the material against the anvil. One shortcoming of knives is that they are subject to dulling forces, and require either protection against dulling, sharpening or replacement.

Materials are bonded throughout the manufacturing process. Discrete pieces of diapers, such as ears, are often bonded to a web such as a chassis web or an extension panel. Typically, bonding is done through various known processes, such as ultrasonic bonding, adhesive bonding, or thermal bonding. In some cases, nonwoven or poly materials are bonded together.

### SUMMARY OF THE INVENTION

Provided are methods and apparatus for modifying webs of material in web processing operations. Using electrostatic means, such as plasma, webs can be cut, webs can be bonded together, and webs can be provided with patterns as desired, such as embossing or providing texture. Plasma is generally referred to as an ionized state of matter. A fourth and most energetic state of matter, plasma is a mixture of electrons, ions and neutral particles in a random motion, such as described in Fridman, A. and L. A. Kennedy, Plasma physics and engineering 2004: CRC press. Plasma occurs over a wide range of pressures for example aurora borealis is low pressure plasma whereas lightening is high pressure plasma, also described in Plasma physics and engineering. The plasma is classified in terms of the electron density (1/cm³) and its temperature (eV). For comparison 1 eV can be calculated in Celsius as 11,357° C. Therefore the plasma temperature can varied based on the electron density. Plasma developed in the laboratory can have the electron density between 10⁶ and 10¹⁸ 1/cm³ and temperature between 1 and 20 eV also described in Plasma physics and engineering.

Most common methods used to create and stabilize the plasma is application of electric field. The electric field is applied between anode and cathode. The common industrial application of plasma is plasma cutting welding of metals and alloys where very high amperage is used to create very high temperature at atmospheric pressure. In another application very low current but very high voltage is used to create a corona which has several industrial applications. Recent application of plasma in biomedical fields is described in U.S. Pat. 8,414,572, and Application 2014/0121656, incorporated by reference. When predetermined voltage and current is applied between anode and cathode, a plasma with required amount of temperature can be stabilized which further can be used to sever the fabric, either continuously or intermittently. Further, the energy generated in the plasma field can be used to melt the fabric placed in the field. When melting is allowed between two or more fabric materials in contact and allowed to solidify, this will fuse/weld the involved fabric materials, which is serves the same purpose to the thermal bonding of nonwoven fabric materials. If two layers of fabric are placed in plasma region, the plasma field can be used to bond the two layers together, or to simultaneously bond the two layers together and sever the layers along an intended severing line.

The plasma techniques of the present invention can be used in several areas of disposable product manufacturing. For instance, the plasma techniques can be used for cutting, for bonding and welding webs, for placing patterns onto a web for purposes such as to impart breathability or enhance softness, to improve ring rolling applications, to engrave hardened surfaces, to replace to wire cutting in areas where non-contact and smooth cuts are desired, to replace knife/anvil combinations for slip cutting operations, and to replace die cutting (for instance for leg cut out areas in diapers).

### BRIEF DESCRIPTION OF THE DRAWINGS

FIGS. 1-3 are side views of a plasma unit operating on a traveling web or webs;

FIG. 4 is a microscopic view of a web of material acted upon by plasma;

FIG. 5 is a microscopic view of a web of material intermittently acted upon by plasma;

FIG. 6 is a microscopic view of a web of material severed by plasma;

FIG. 7 is a microscopic view of a web of material showing individual non-woven fabric strands after being acted upon by plasma;

FIG. 8 is a perspective view of a pair of profiled die rolls with a generated plasma pattern generated between them acting upon a web of material, shown in closeup in FIG. 8A;

FIG. 9 is a perspective view of a profiled die roll and a smooth roll with a generated plasma pattern generated between them acting upon a web of material, shown in closeup in FIG. 9A.;

FIG. 10 is an alternate embodiment of a pair of smooth profile electric die rolls with a generated plasma pattern generated between them acting upon a web of material, shown in closeup in FIG. 10A;

FIG. 11 is an alternate embodiment of a pair of smooth profile electric die rolls with a generated plasma pattern generated between them acting upon a web of material, the smooth profile electric die rolls executing a side cutout pattern;

FIG. 12 is an alternate embodiment of a pair of smooth profile electric die rolls with a generated plasma pattern generated between them acting upon a web of material, the smooth profile electric die rolls executing a cookie cutout pattern;

FIG. 13 is a side view of a vacuum assisted scrap material recovery system for recovering a cutout of a web.

### DESCRIPTION OF THE PREFERRED EMBODIMENT

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention.

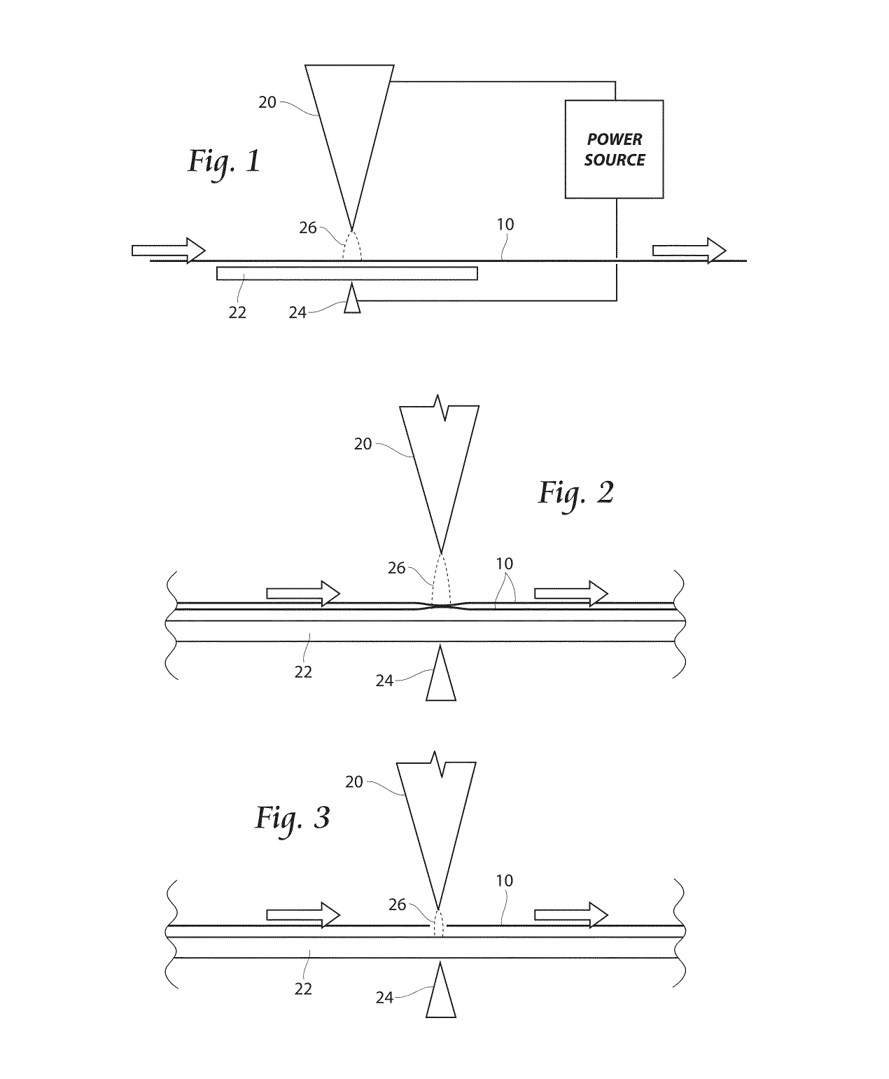

Referring now to FIG. 1, a side view of a plasma unit 20 operating on a traveling web 10 or webs 10 is shown. Predetermined power is supplied between anode 20 and cathode 24, which creates plasma 26 with required heat. The size shape and location of the anode 20 and cathode 24 can be changed in order to locate or direct the plasma for intended action. They can be interchanged based on the specific conditions of plasma to be achieved. Cathode 24 is connected to the power source and located underneath the base plate 22. When a poly or a nonwoven materials is introduced atop the base plate 22, generated plasma between two electrodes (22 and 24) act upon the poly or nonwoven 10 as desired. If desired, the plasma field 26 can act to sever the fabric 10 (FIG. 3). If two layers of fabric 10 are placed on the base plate 22, which can be formed of polycarbonate, the plasma field 26 can be used to bond the two layers 10 together (FIG. 2), or to simultaneously bond the two layers 10 together and sever the layers along an intended severing line.

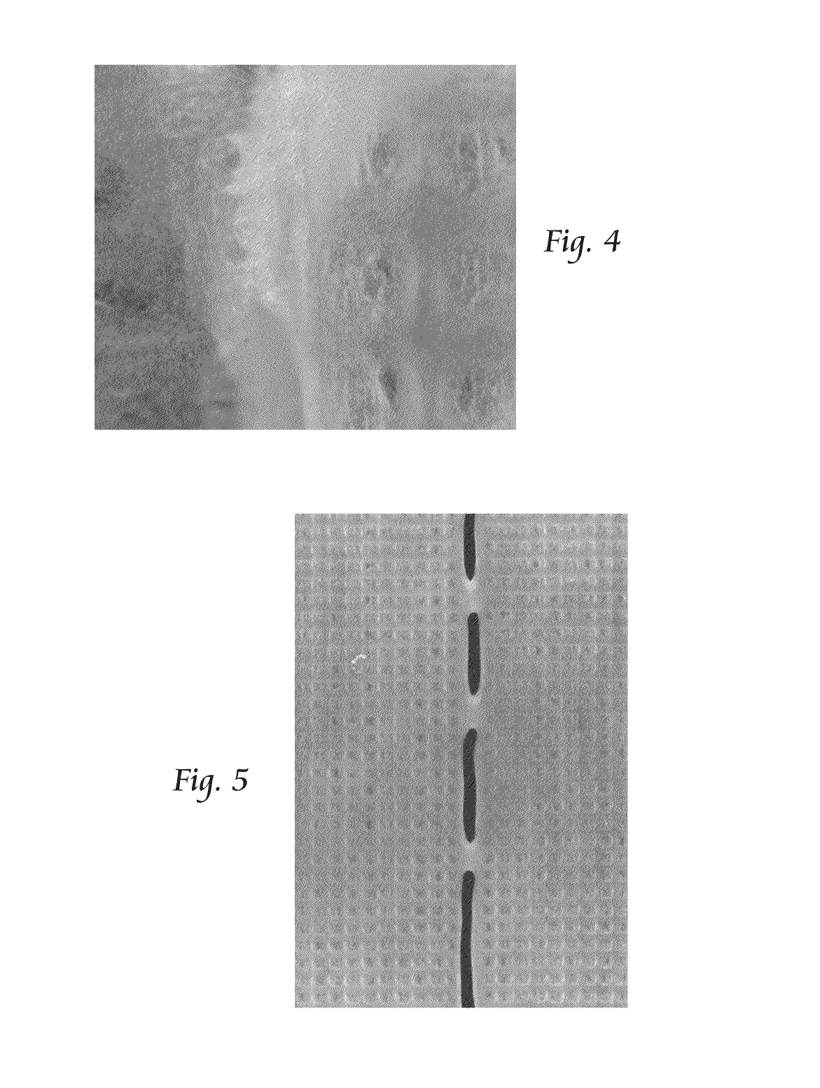

Referring now to FIG. 4, a microscopic view of two webs of poly material 10 acted upon by plasma 26 are shown. In this figure, it is seen that individual particles of the two poly layers 10 have become fused or welded together under the action of plasma.

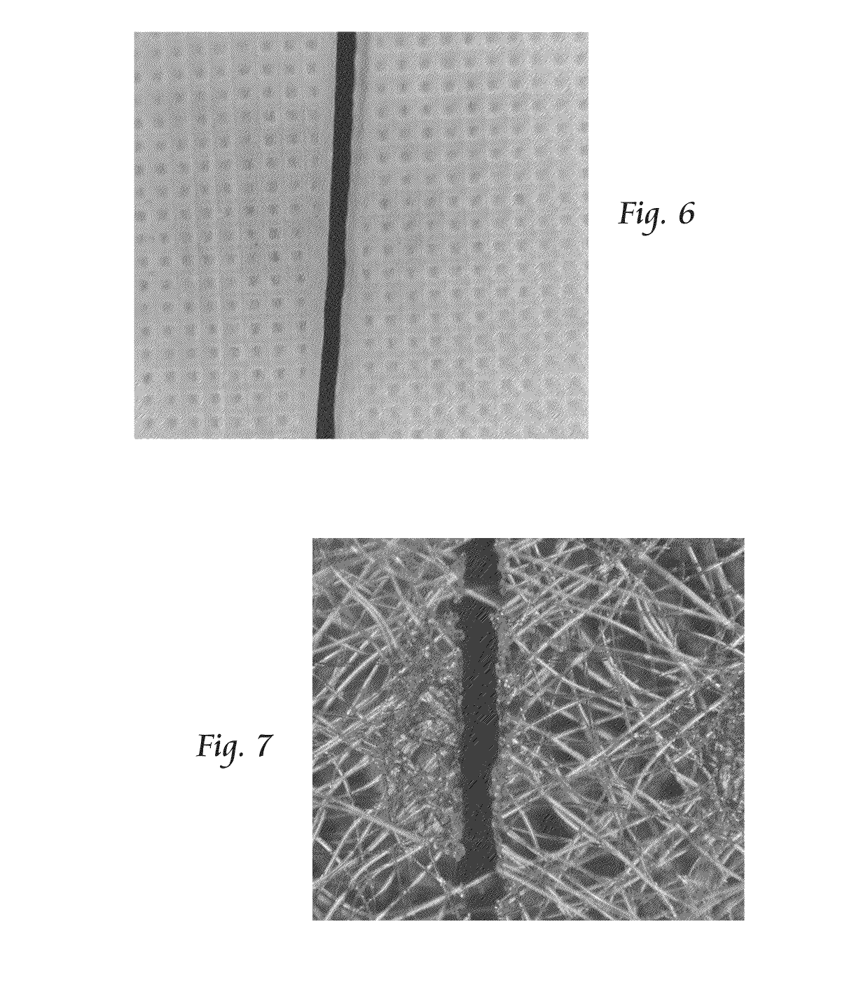

Referring now to FIG. 5, a microscopic view of a web 10 of poly material is seen having been intermittently acted upon by plasma, and FIG. 6 shows a continuous severing of a poly web 10 severed by plasma.

Referring now to FIG. 7, a microscopic view of a web 10 of nonwoven material is shown, showing individual non-woven fabric strands after being acted upon by plasma.

It is noted that in the illustrated embodiments, a single web 10 is shown. However, laminates can be created by the addition of webs 10 of the same, similar, or dissimilar material layers. For instance, webs of elastic material can be combined (bonded) using electrostatic means if more than one web 10 is passed through the system.

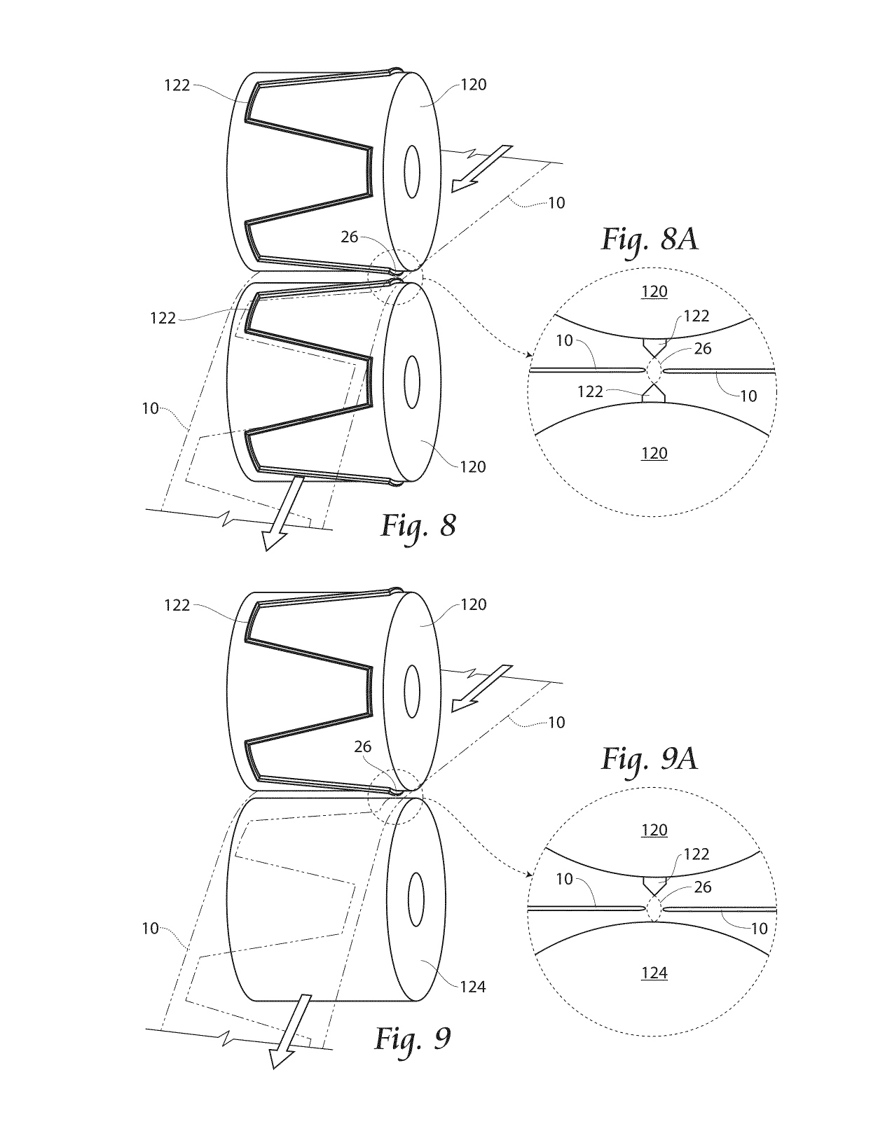

Referring now to FIG. 8, one embodiment of the present invention is shown. A pair of profiled die rolls 120, and in particular a plasma pattern 26 generated between them, act upon a web passing between the rolls. In this embodiment, each roll has a patterned edge or profile 122 (which can take any shape), and as the two rolls rotate, the plasma follows the die profile between the two rolls, due to the high points of the die roll patterns 122 being the most proximal to one another (the smallest gap between the two rolls). The plasma 26 forms at this smallest gap point, where a web 10 is passed between the rolls 120, and the web 10 can be acted upon as desired in a controlled fashion.

Referring now to FIG. 9, in an alternate embodiment, a single profiled die roll 120 cooperates with a smooth roll 124, which can be formed of ceramic for example. In this embodiment, between the two rolls exists a controlled plasma generating gap location to control plasma pattern 26, and as the two rolls 120 and 124 rotate, the plasma pattern remains in place and follows the profile 122 on the profiled die roll. It is noted that plasma pattern 26 is referred to in this embodiment as being a single point location. In this embodiment, if a cross-machine direction cut is desired, the web 10 could be moved in a cross-machine direction, or skewed relative to machine direction as shown to approximate a cross-machine direction or transverse cut line. A radius-line of plasma could be created alternative to a single point plasma generation.

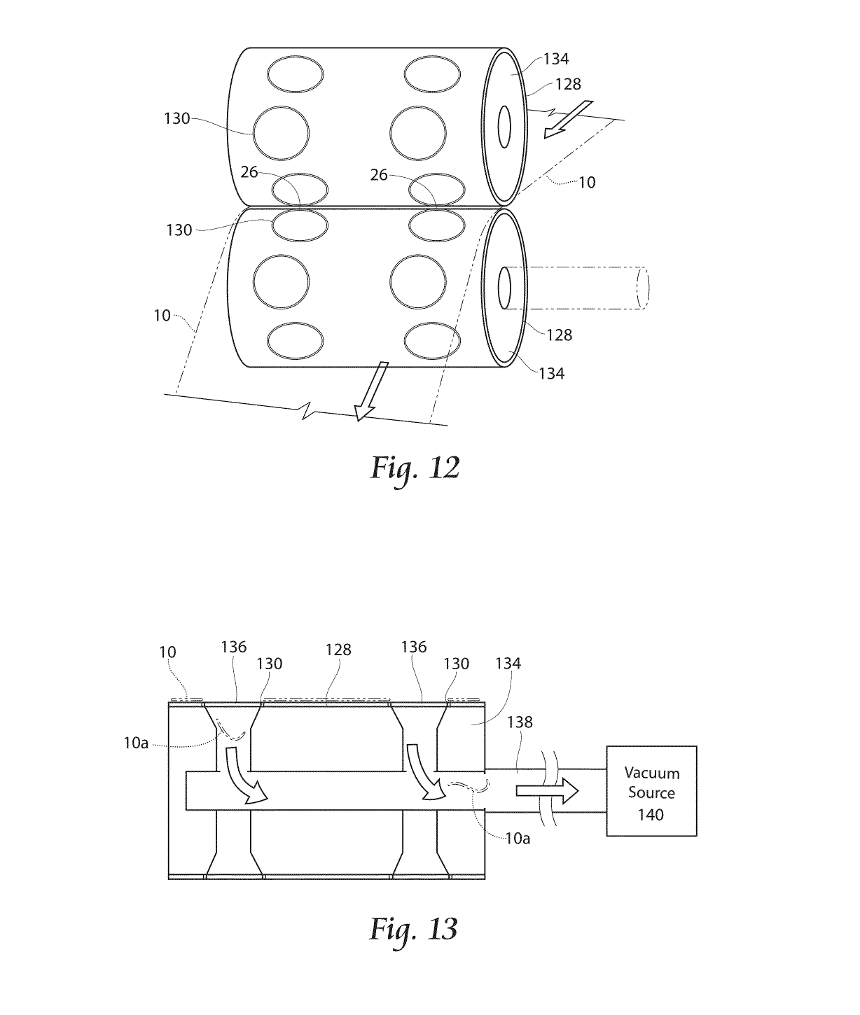

In the embodiments shown in FIGS. 8 and 9, different methods of web control can be used to guide the web 10. Web control could be applying vacuum to rolls 120 and 124 through vacuum voids (not shown). Alternatively, different web control methods could be used depending on the type of cutting the plasma unit is intended to provide according to the instant process need, such as slitting (e.g., FIG. 6), cross-cutting, profile cutting (e.g., FIG. 8), side-web notch removal (such as a leg cutout of a running web shown in FIG. 11) or cookie-cutting of individual shapes out of the running web (FIG. 12). Alternative to vacuum rolls, a draw roll process could be used, in which web tension is maintained as web is drawn through the rolls 120 and 124.

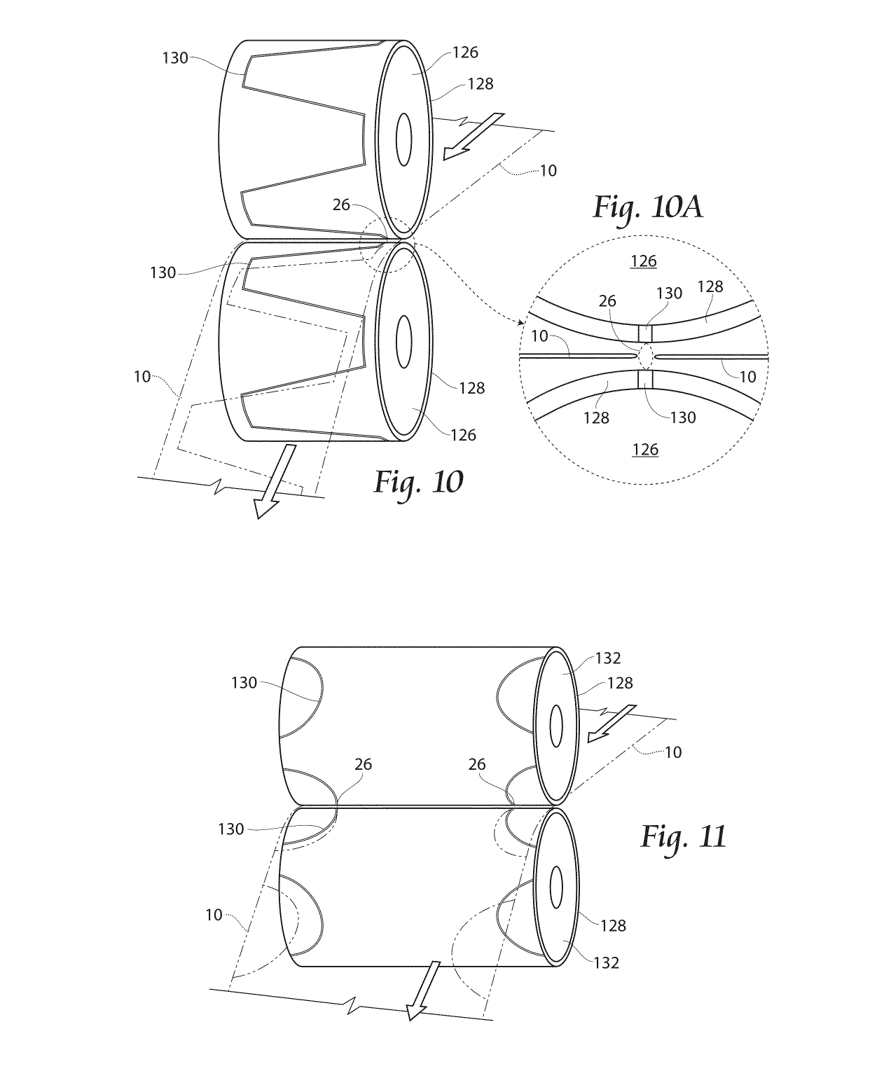

Referring now to FIG. 10, an alternate embodiment of a pair of smooth profile electric die rolls 126 is shown with a generated plasma pattern 26 generated between electrically conductive surfaces 130 on them acting upon a web of material, shown in closeup in FIG. 10A. In this embodiment smooth profile electric die rolls 126 can be formed of two different materials. A first electrically conductive material 130 can be placed into a desired pattern within an electrically non-conductive material 128 (e.g., ceramic). To drive the web 10 in this effective virtual edge profile embodiment, a pattern or profiled shape of electrically conductive material (metallic) could be combined with a non-conductive material (e.g., ceramic) and in this case the web 10 could be wrapped around the roll for control, eliminating the need for an opposing roll. In an alternative embodiment, a single smooth profile electric die roll 126 could be used, with a stationary opposing electrical contact placed in proximity to electrically conductive material 130 to achieve the plasma pattern 26 acting upon web 10 as desired.

Referring now to FIG. 11, an alternate embodiment of a pair of smooth profile electric die rolls 132 with a generated plasma pattern 26 generated between patterns 130 of electrically conductive material 130 acting upon a web of material is shown. The illustrated embodiment shows the smooth profile electric die 132 rolls executing a side cutout pattern.

Referring now to FIG. 12, an alternate embodiment of a pair of smooth profile electric die rolls 134 with a generated plasma pattern 26 generated between cookie cutter patterns 130 acting upon a web of material 10 is shown. Because this embodiment will create scrap pieces, referring now to FIG. 13, a side view of a vacuum assisted scrap material recovery system for recovering a cutout 10a of web 10 is shown. A scrap piece 10 is drawn down into the roll 130 through a surface void 136 in the roll, with vacuum from source 140 withdrawing the scrap pieces 10a into a waste-stream through a hollow shaft 138 of the roll. Alternatively, surface methods such as a ripper roll (See U.S. Pat. No. 8,293,056 incorporated herein by reference) or surface suction nozzles positioned over the scrap regions 136 could be used. In FIG. 13, hollow shaft 138 can be stationary or driven, while roll 134 is driven independently or jointly.

The foregoing is considered as illustrative only of the principles of the invention. Furthermore, since numerous modifications and changes will readily occur to those skilled in the art, it is not desired to limit the invention to the exact construction and operation shown and described. While the preferred embodiment has been described, the details may be changed without departing from the invention, which is defined by the claims.

We claim:

1. A method for processing webs of material., the system comprising:
supplying an anode and a cathode and a plasma between said anode and cathode; and
passing at least one web of material through said plasma to process said web of material by at least one of severing and bonding said web of material.

2. A method according to claim 1, said method further comprising carrying at least one of said anode and said cathode on a first, rotating body, carrying at least one of said anode and said cathode on a second rotating body and passing said web through said plasma between said first, and second roam bodies.

3. A method according to claim. 2, said plasma being generated between a raised surface on at least one of said first and second rotating bodies.

4. A method according to claim 2, said method further comprising severing a discrete piece from said web and drawing said discrete piece into at least one of said first and said second rotating bodies.
